(19) United States
(12) Patent Application Publication
(10) Pub. No.: US 2012/0164410 A1
(43) Pub. Date: Jun. 28, 2012

(54) COATED ARTICLE AND METHOD FOR MANUFACTURING COATED ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); SHYAN-JUH LIU, Tu-Cheng (TW); CONG LI, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/084,655

(22) Filed: Apr. 12, 2011

(30) Foreign Application Priority Data
Dec. 23, 2010 (CN) 201010602367.2

(51) Int. Cl. B32B 7/02; B32B 9/00; C23C 14/35; C23C 14/06; B32B 3/00; B32B 15/04

(52) U.S. Cl. 428/212; 428/336; 428/457; 204/192.12; 204/192.15; 428/698

(57) ABSTRACT

An coated article includes a substrate; and a lubricant layer deposited on the substrate; wherein the lubricant layer is a molybdenum sulphur boron nitride layer and comprises molybdenum sulfur boron nitride (MoSBN) having a molybdenum disulfide phase and a boron nitride phase.

### BACKGROUND

1. Technical Field

The exemplary disclosure generally relates to coated articles and method for manufacturing the coated articles.

2. Description of Related Art

Molybdenum disulfide (MoS₂) has been used to deposit a coating on metal bases of cutting tools or molds for reducing friction. However, when the cutting tools with the MoS₂ coatings are used to cut magnesium alloy and/or aluminum alloy, the magnesium alloy and/or aluminum alloy can stick to the cutting tools because the wettability between the MoS₂ coating and the aluminum alloy and/or magnesium alloy is low.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary coated article and method for manufacturing the coated article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of coated article.

FIG. 2 is a schematic view of a magnetron sputtering coating machine for manufacturing the coated article in FIG. 1.

### DETAILED DESCRIPTION

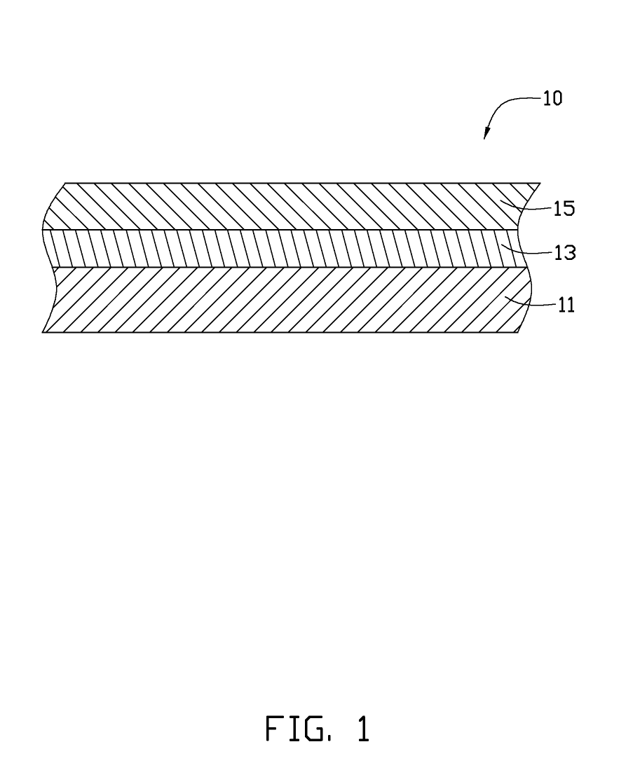

Referring to FIG. 1, an exemplary embodiment of a coated article 10 includes a substrate 11, a bonding layer 13 deposited on the substrate 11, and a lubricant layer 15 deposited on the bonding layer 13 opposite to the substrate 11. The coated article 10 may be a cutting tool, a mold, or housing for electronic devices. The substrate 11 may be made of stainless steel, high speed steel or die steel. The bonding layer 13 is a molybdenum layer and has a thickness between 200 nanometers and 300 nanometers. The lubricant layer 15 is a molybdenum sulfur boron nitride (MoSBN) layer and has a thickness between 0.8 micrometers and 1.3 micrometers. The lubricant layer 15 comprises molybdenum sulfur boron nitride (MoSBN) having a molybdenum disulfide phase and a boron nitride phase. The molybdenum disulfide phase causes the lubricant layer 15 to have good lubricity, and the boron nitride phase causes the lubricant layer 15 to have good corrosion resistance and good oxidation resistance.

The bonding layer 13 and the lubricant layer 15 may both be deposited by magnetron sputtering process. The chemical stability of the bonding layer 13 is between the chemical stability of the substrate 10 and the chemical stability of the lubricant layer 15, and a coefficient of thermal expansion of the bonding layer 13 is between the coefficient of thermal expansion of the substrate 10 and the coefficient of thermal expansion of the lubricant layer 15. Thus, the bonding layer 13 improves binding between the substrate 10 and the lubricant layer 15 so the lubricant layer 15 can be firmly deposited on the substrate 10.

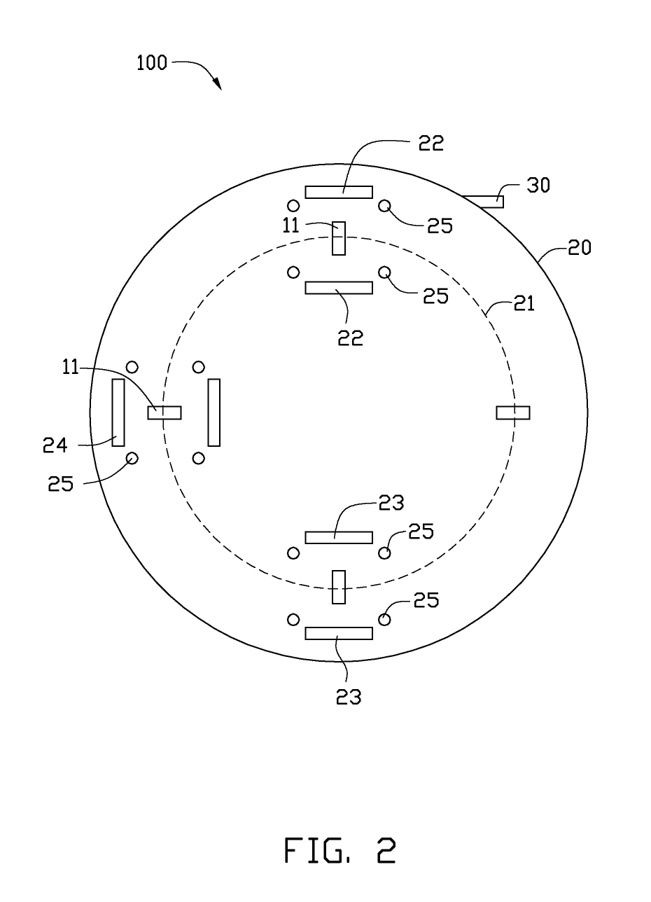

Referring to FIG. 2, a method for manufacturing the coated article 10 may include at least the following steps.

Providing a substrate 11. The substrate 11 may be made of stainless steel, high speed steel or die steel.

Pretreating the substrate 11, by washing with a solution (e.g., Alcohol or Acetone) in an ultrasonic cleaner, to remove impurities and contaminates, such as grease, or dirt. The substrate 11 is dried. The substrate 11 is then cleaned by argon plasma cleaning.

Providing a vacuum sputtering coating machine 100. The vacuum sputtering coating machine 100 includes a sputtering coating chamber 20 and a vacuum pump 30 connecting to the sputtering coating chamber 20. The vacuum pump 30 is used to pump the air out the sputtering coating chamber 20. The vacuum sputtering coating machine 100 further includes a rotating bracket 21, two first targets 22, two second targets 23, two third targets 23 and a plurality of gas inlets 25. The rotating bracket 21 rotates the substrate 11 in the sputtering coating chamber 20 relative to the first targets 22 and the second targets 23. The first targets 22 face each other, and are respectively located on one side of the rotating bracket 21. The second targets 23 face each other, and are respectively located on opposite sides of the rotating bracket 21. The third targets 24 face each other, and are respectively located on opposite sides of the rotating bracket 21. In this exemplary embodiment, the first targets 22 are molybdenum disulfide (MoS2) targets, the second targets 23 are boron nitride targets, the third targets 24 are molybdenum targets.

An bonding layer 13 is deposited on the substrate 11. The vacuum level inside the sputtering coating chamber 20 is set to about 3.0×10-3 Pa. The temperature in the sputtering coating chamber 20 is set between about 100° C. (Celsius degree) and about 200° C. Argon is fed into the sputtering coating chamber 20 at a flux between about 300 Standard Cubic Centimeters per Minute (sccm) and about 400 sccm from the gas inlets 25. The third targets 24 in the sputtering coating chamber 20 are evaporated at a power between about 2 kW and about 5 kW. A bias voltage applied to the substrate 11 may be between about −100 volts and about −300 volts, for between about 20 minutes and about 40 minutes, to deposit the bonding layer 13 on the substrate 11.

An lubricant layer 15 is deposited on the bonding layer 13. The temperature in the sputtering coating chamber 20 is set between about 100° C. and about 200° C. Argon is fed into the sputtering coating chamber 20 at a flux between about 120 sccm and 350 sccm from the gas inlets 25. The first targets 22 in the sputtering coating chamber 20 are evaporated at a power between about 100 W and about 300 W. The second targets 23 in the sputtering coating chamber 20 are evaporated at a power between about 100 W and about 500 W. A bias voltage applied to the substrate 11 may be between about −100 volts and about −300 volts, for between about 90 minutes and about 120 minutes, to deposit the lubricant layer 15 on the bonding layer 13.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coated article, comprising:
a substrate; and
a lubricant layer deposited on the substrate;
wherein the lubricant layer is a molybdenum sulphur boron nitride layer and comprises molybdenum disulfide phase and boron nitride phase.

2. The coated article as claimed in claim 1, wherein the lubricant layer has a thickness between 0.8 micrometers and 1.3 micrometers.

3. The coated article as claimed in claim 1, wherein the substrate is made of stainless steel, high speed steel or die steel.

4. The coated article as claimed in claim 1, further comprising a bonding layer formed between the substrate and the lubricant layer.

5. The coated article as claimed in claim 4, wherein the chemical stability of the bonding layer is between the chemical stability of the substrate and the chemical stability of the lubricant layer, and a coefficient of thermal expansion of the bonding layer is between the coefficient of thermal expansion of the substrate and the coefficient of thermal expansion of the lubricant layer.

6. The coated article as claimed in claim 5, wherein the bonding layer is a molybdenum layer.

7. The coated article as claimed in claim 6, wherein the bonding layer is a molybdenum layer and has a thickness between 200 nanometers and 300 nanometers.

8. The coated article as claimed in claim 1, wherein the bonding layer and the lubricant layer are both deposited by magnetron sputtering process.

9. A method for manufacturing a coated article comprising steps of:
providing a substrate;
depositing a bonding layer on the substrate by magnetron sputtering; and
depositing an lubricant layer on the bonding layer by magnetron sputtering.

10. The method of claim 9, wherein during depositing the bonding layer on the substrate, the substrate is retained in a sputtering coating chamber of a magnetron sputtering coating machine, the sputtering coating chamber has a molybdenum target therein; the vacuum level inside the sputtering coating chamber is set to about 3.0×10-3 Pa; the temperature in the sputtering coating chamber is set between about 100° C. and about 200° C.; argon is fed into the sputtering coating chamber at a flux between about 300 Standard Cubic Centimeters per Minute and about 400 sccm; the molybdenum target is evaporated at a power between about 2 kW and about 5 kW; a bias voltage applied to the substrate is between about −100 volts and about −300 volts, for between about 20 minutes and about 40 minutes, to deposit the bonding layer on the substrate.

11. The method of claim 9, wherein during depositing the lubricant layer on the bonding layer, the substrate is retained in a sputtering coating chamber of a magnetron sputtering coating machine, the sputtering coating chamber has a molybdenum disulfide target and a boron nitride target therein; the temperature in the sputtering coating chamber is set between about 100° C. and about 200° C.; argon is fed into the sputtering coating chamber at a flux between about 120 sccm and 350 sccm; the molybdenum disulfide target is evaporated at a power between about 100 W and about 300 W; the boron nitride target is evaporated at a power between about 100 W and about 500 W; a bias voltage applied to the substrate is between about −100 volts and about −300 volts, for between about 90 minutes and about 120 minutes, to deposit the lubricant layer on the bonding layer.
